(19) United States
(12) Patent Application Publication
(10) Pub. No.: US 2016/0073515 A1
(43) Pub. Date: Mar. 10, 2016

(54) WIRING BOARD WITH BUILT-IN ELECTRONIC COMPONENT AND METHOD FOR MANUFACTURING THE SAME

(71) Applicant: IBIDEN CO., LTD., Ogaki (JP)

(72) Inventors: Keisuke SHIMIZU, Ogaki (JP); Makoto TERUI, Ogaki (JP); Ryojiro TOMINAGA, Ogaki (JP); Tsutomu YAMAUCHI, Ogaki (JP)

(73) Assignee: IBIDEN CO., LTD., Ogaki (JP)

(21) Appl. No.: 14/847,396

(22) Filed: Sep. 8, 2015

(30) Foreign Application Priority Data
Sep. 8, 2014 (JP) 2014-182087

(51) Int. Cl. H05K 3/32; H05K 3/46; H05K 3/40; H05K 3/00; H05K 1/18; H05K 1/11

(52) U.S. Cl. CPC H05K 3/32; H05K 1/189; H05K 1/115; H05K 3/4038; H05K 3/0026; H05K 3/4644; H05K 2201/09827

(57) ABSTRACT

A wiring board with a built-in electronic component includes a substrate having a cavity, an electronic component accommodated in the cavity and having electrode terminals, an insulating layer formed on the substrate such that the insulating layer is covering the electronic component in the cavity, and via conductors formed through the insulating layer and including first via conductors and second via conductors such that the second via conductors are connected to the electrode terminals of the electronic component, respectively. The via conductors are formed in via formation holes penetrating through the insulating layer, respectively, and the via formation holes include first via formation holes and second via formation holes such that the second via formation holes are exposing the electrode terminals of the electronic component, respectively, and that a second via formation hole has a diameter which is smaller than a diameter of a first via formation hole.

### CROSS-REFERENCE TO RELATED APPLICATIONS

The present application is based upon and claims the benefit of priority to Japanese Patent Application No. 2014-182087, filed Sep. 8, 2014, the entire contents of which are incorporated herein by reference.

### BACKGROUND OF THE INVENTION

1. Field of the Invention

The present invention relates to a wiring board with a built-in electronic component having via conductors connected to electrode terminals of the electronic component, and to a method for manufacturing the wiring board with a built-in electronic component.

2. Description of Background Art

International Publication No. 2007/129545 describes a wiring board with a built-in electronic component, in which via formation holes are formed by laser processing in an insulating layer laminated on an electronic component and via conductors are formed in the via formation holes. The entire contents of this publication are incorporated herein by reference.

### SUMMARY OF THE INVENTION

According to one aspect of the present invention, a wiring board with a built-in electronic component includes a substrate having a cavity, an electronic component accommodated in the cavity and having electrode terminals, an insulating layer formed on the substrate such that the insulating layer is covering the electronic component in the cavity, and via conductors formed through the insulating layer and including first via conductors and second via conductors such that the second via conductors are connected to the electrode terminals of the electronic component, respectively. The via conductors are formed in via formation holes penetrating through the insulating layer, respectively, and the via formation holes include first via formation holes and second via formation holes such that the second via formation holes are exposing the electrode terminals of the electronic component, respectively, and that a second via formation hole has a diameter which is smaller than a diameter of a first via formation hole.

According to another aspect of the present invention, a method for manufacturing a wiring board with a built-in electronic component includes accommodating an electronic component having electrode terminals in a cavity of a substrate, forming an insulating layer on the substrate such that the insulating layer is covering the electronic component in the cavity, applying laser processing to the insulating layer such that via formation holes are formed penetrating through the insulating layer, and forming via conductors in the via formation holes such that the via conductors are formed through the insulating layer. The applying of the laser processing includes forming the via hole formation holes including first via formation holes and second via formation holes such that the second via formation holes are exposing the electrode terminals of the electronic component, respectively, and that a second via formation hole has a diameter which is smaller than a diameter of a first via formation hole, and the forming of the via conductors includes forming the via conductors including first via conductors and second via conductors such that the second via conductors are connected to the electrode terminals of the electronic component, respectively.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring board with a built-in electronic component according to an embodiment of the present invention;

FIG. 2 is a cross-sectional view around an electronic component of the wiring board with a built-in electronic component;

FIG. 3 is a cross-sectional view of a first via conductor and a second via conductor;

FIG. 4 is a cross-sectional view of a substrate with a cavity;

FIG. 5 is a cross-sectional view of the substrate with a cavity;

FIGS. 6A and 6B are cross-sectional views illustrating manufacturing processes of the substrate with a cavity;

FIGS. 7A and 7B are cross-sectional views illustrating manufacturing processes of the substrate with a cavity;

FIGS. 8A and 8B are cross-sectional views illustrating manufacturing processes of the substrate with a cavity;

FIGS. 9A and 9B are cross-sectional views illustrating manufacturing processes of the substrate with a cavity;

FIGS. 10A and 10B are cross-sectional views illustrating manufacturing processes of the wiring board with a built-in electronic component;

FIGS. 11A and 11B are cross-sectional views illustrating manufacturing processes of the wiring board with a built-in electronic component;

FIGS. 12A and 12B are cross-sectional views illustrating manufacturing processes of the wiring board with a built-in electronic component;

FIG. 13 is a cross-sectional view illustrating a manufacturing process of the wiring board with a built-in electronic component;

FIG. 14 is a cross-sectional view illustrating a manufacturing process of the wiring board with a built-in electronic component;

FIG. 15 is a cross-sectional view illustrating a manufacturing process of the wiring board with a built-in electronic component;

FIG. 16 is a cross-sectional view illustrating a manufacturing process of the wiring board with a built-in electronic component;

FIG. 17A-17C are cross-sectional views illustrating manufacturing processes of a substrate with a cavity according to a modified embodiment; and

FIGS. 18A and 18B are cross-sectional views illustrating manufacturing processes of the substrate with a cavity according to the modified embodiment.

### DETAILED DESCRIPTION OF THE EMBODIMENTS

The embodiments will now be described with reference to the accompanying drawings, wherein like reference numerals designate corresponding or identical elements throughout the various drawings.

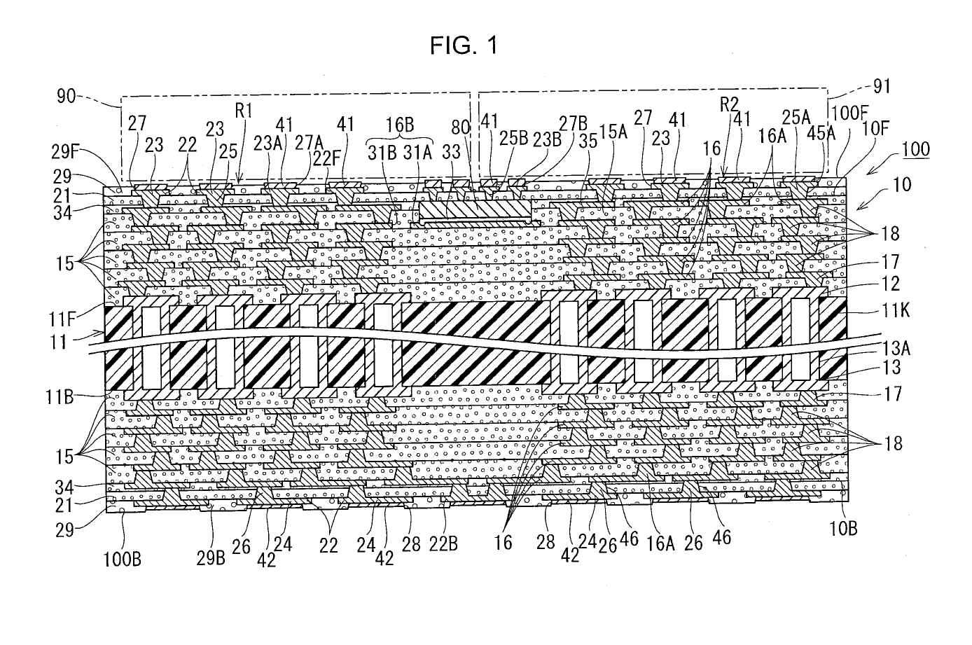

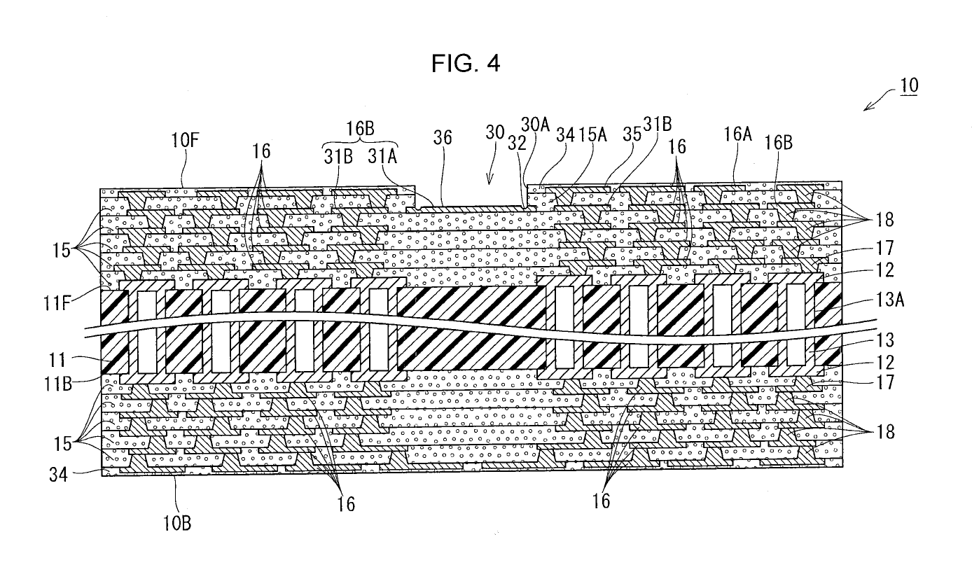

In the following, an embodiment of the present invention is described based on FIG. 1-16. As illustrated in FIG. 1, a wiring board 100 with a built-in electronic component according to the present embodiment has a structure in which an outer side build-up insulating layer 21 and an outer side build-up conductor layer 22 are laminated on each of both front and back surfaces of a substrate 10 with a cavity (see FIG. 4) (an interposer 80 as an electronic component being accommodated in a cavity 30) and the outer side build-up conductor layer 22 is covered by a solder resist layer 29. The solder resist layer 29 forms an F surface (100F), which is a front side surface of the wiring board 100 with a built-in electronic component, and a B surface (100B), which is a back side surface of the wiring board 100. The solder resist layer 29 has a thickness of about 7-25 μm. The outer side build-up insulating layer 21 has a thickness of about 15 μm. The outer side build-up conductor layer 22 has a thickness of about 15 μm. The thickness of the solder resist layer 29 is defined by a distance from an upper surface of the outer side build-up conductor layer 22 to an upper surface of the solder resist layer 29. Further, a thickness of each build-up insulating layer among the outer side build-up insulating layer 21 and build-up insulating layers 15 (to be described later) is defined by a distance between conductor layers above and below the build-up insulating layer.

As illustrated in FIG. 4, the substrate 10 with a cavity has a multilayer structure in which the build-up insulating layers 15 and build-up conductor layers 16 are alternately laminated on each of both an F surface (11F), which is a front side surface of a core substrate 11, and a B surface (11B), which is a back side surface of the core substrate 11.

The core substrate 11 has a thickness of about 700 μm. A core conductor layer 12 is formed on each of both the front and back surfaces of the core substrate 11. The core conductor layer 12 has a thickness of about 35 μm. The build-up insulating layers 15 are each formed of an insulating material and each have a thickness of about 10-30 μm. The build-up conductor layers 16 are each formed of metal (such as copper) and each have a thickness of about 10-15 μm.

The front side core conductor layer 12 and the back side core conductor layer 12 are connected by through-hole conductors 13 that penetrate through the core substrate 11. The through-hole conductors 13 are formed, for example, by forming copper plating on wall surfaces of through holes (13A) that penetrate through the core substrate 11.

An innermost build-up conductor layer 16, which is closest to the core substrate 11, and the core conductor layer 12 are connected by via conductors 17 that penetrate through an innermost build-up insulating layer 15. Further, build-up conductor layers (16, 16) that are adjacent to each other in a lamination direction are connected by via conductors 18 that penetrate through a build-up insulating layer 15 that is positioned between the build-up conductor layers (16, 16).

A conductor circuit layer (31B) and a plane layer (31A) are formed in a second build-up conductor layer (16B) that is among the build-up conductor layers 16 laminated on the F surface (11F) side of the core substrate 11 and is positioned second from an outer side. The plane layer (31A) is formed in a solid shape as a ground layer that is grounded. The plane layer (31A) is formed near a central portion of the substrate 10 with a cavity, and the conductor circuit layer (31B) is formed in a manner sandwiching the plane layer (31A) from both sides.

In a first build-up conductor layer (16A) that is among the build-up conductor layers 16 laminated on the F surface (11F) side of the core substrate 11 and is positioned outermost, an outer side conductor circuit layer 35 is formed that is connected via the via conductor 18 to the conductor circuit layer (31B). Further, a protective layer 34 is laminated on the first build-up conductor layer (16A). The protective layer 34 is formed of the same material as the build-up insulating layers 15. The protective layer 34 has a thickness of about 7-15 μm and is thinner than each of the build-up insulating layers 15. The protective layer 34 forms an F surface (10F), which is a front side surface of the substrate 10 with a cavity, and a B surface (10B), which is a back side surface of the substrate 10 with a cavity. However, it is also possible that the protective layer 34 is not formed on the back side surface of the substrate 10 with a cavity.

The cavity 30 that has an opening (30A) on the F surface (10F) is formed in the substrate 10 with a cavity. The cavity 30 penetrates through a first build-up insulating layer (15A) that is positioned on an outermost side and the protective layer 34, and exposes the plane layer (31A) as a bottom surface.

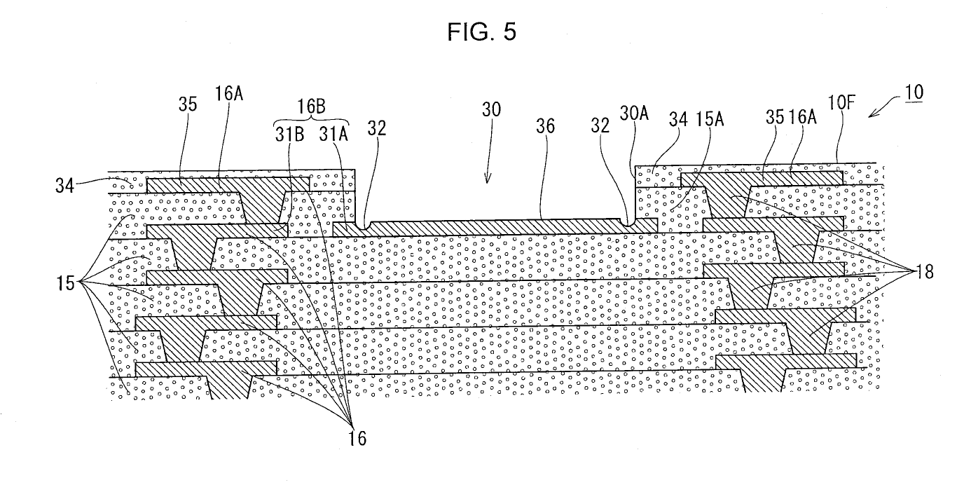

As illustrated in FIG. 5, an area of the opening (30A) of the cavity 30 is smaller than an area of the plane layer (31A), and an outer peripheral portion of the plane layer (31A) protrudes to an outer side of the cavity 30. In other words, the plane layer (31A) forms the entire bottom surface of the cavity 30. Further, a recess 32 is formed in an outer peripheral portion of the portion of the plane layer (31A) that is exposed as the bottom surface of the cavity 30. The recess 32 has a depth of about 0.5-3 μm. A roughened layer 36 is formed on a surface of the portion of the plane layer (31A) that is exposed as the bottom surface of the cavity 30.

As illustrated in FIG. 1, element mounting regions (R1, R2) for mounting semiconductor elements (90, 91) are formed on an F surface (100F) of the wiring board 100 with a built-in electronic component. The cavity 30 is formed on an inner side of a boundary portion of the element mounting regions (R1, R2). The interposer 80 that electrically connects the semiconductor elements (90, 91) mounted in the element mounting regions (R1, R2) is accommodated in the cavity 30.

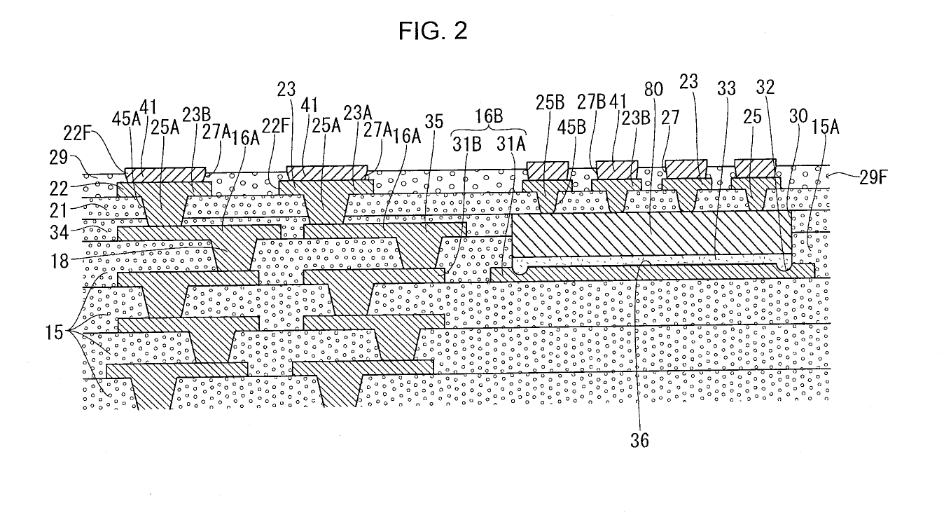

Specifically, as illustrated in FIG. 2, a bonding layer 33 is formed on the plane layer (31A) that is exposed as the bottom surface of the cavity 30, and the interposer 80 is mounted on the bonding layer 33. Here, due to the recess 32 of the plane layer (31A), an anchor effect is exerted on the bonding layer 33, and peeling of the bonding layer 33 from the plane layer (31A) is suppressed. In addition, due to the roughened layer 36 that is formed on the surface of the plane layer (31A) that is exposed as the bottom surface of the cavity 30, peeling of the bonding layer 33 from the plane layer (31A) is further suppressed.

As illustrated in FIG. 2, in an F-surface solder resist layer (29F) that forms the F surface (100F) of the wiring board 100 with a built-in electronic component, openings 27 are formed that respectively expose portions of an F-surface outer side build-up layer (22F) as conductor pads 23, the F-surface outer side build-up layer (22F) being one of the outer side build-up layers 22 that is positioned on the F surface (100F) side. Specifically, the conductor pads 23 include first conductor pads (23A) that formed on an outer side of the cavity 30 when viewed from a thickness direction and second conductor pads (23B) that overlap with the interposer 80. The openings 27 include first openings (27A) that respectively expose the first conductor pads (23A) and second openings (27B) that respectively expose the second conductor pads (23B).

The conductor pads 23 are connected via conductor vias 25 to the outer side conductor circuit layer 35 of the first build-up conductor layer (16A) or the interposer 80. Specifically, the first conductor pads (23A) are connected via first via conductors (25A) to the outer side conductor circuit layer 35, and the second conductor pads (23B) are connected via second via conductors (25B) to the interposer 80. According to the present embodiment, the outer side conductor circuit layer 35 corresponds to a “conductor circuit layer,” and the first build-up insulating layer (15A) of the substrate 10 with a cavity corresponds to an “inner side insulating layer.”

The first via conductors (25A) are formed by filling plating in first via formation holes (45A) that penetrate through the outer side build-up insulating layer 21 and the bonding layer 34. The second via conductors (25B) are formed by filling plating in second via formation holes (45B) that penetrate through the outer side build-up insulating layer 21. The first via formation holes (45A) are formed on the outer side of the cavity 30 when viewed from the thickness direction. The second via formation holes (45B) are formed on the interposer 80 and expose electrode terminals (not illustrated in the drawings) that are formed on an upper surface of the interposer 80 The second via formation holes (45B) have a hole diameter smaller than that of the first via formation holes (45A). Specifically, the hole diameter of the first via formation holes (45A) is 50-80 μm, and the hole diameter of the second via formation holes (45B) is 20-40 μm. Further, an interval (pitch) between the first via formation holes (45A, 45A) is 70-160 μm, and an interval (pitch) between the second via formation holes (45B, 45B) is 35-80 μm. According to the present embodiment, the outer side build-up insulating layer 21 corresponds to an “outer side insulating layer.” Further, the first via formation holes (45A) and the second via formation holes (45B) form “via formation holes.”

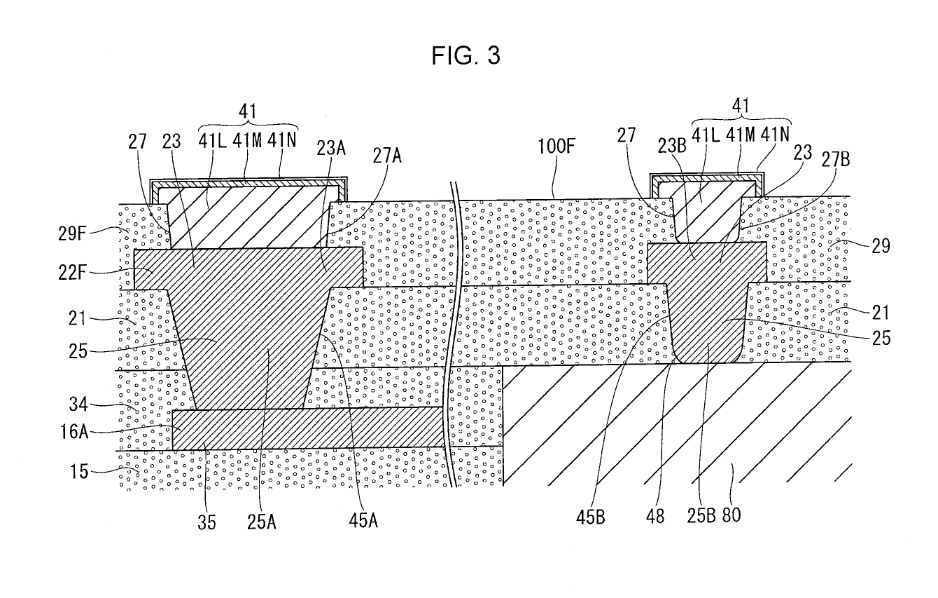

As illustrated in FIG. 3, the first via formation holes (45A) are each formed in a tapered shape that is gradually reduced in diameter as it approaches a bottom on the first build-up conductor layer (16A) side. Further, the second via formation holes (45B) are each formed in a tapered shape that has a taper angle smaller than that of the first via formation holes (45A). On an inner peripheral surface of a bottom portion (end portion on the interposer 80 side) of each of the second via formation holes (45B), a curved diameter-reducing portion 48 that is gradually reduced in diameter as it approaches an end on the bottom side (approaches the interposer 80) is formed.

F-surface plating layers 41 are respectively formed on the first conductor pads (23A) and the second conductor pads (23B). The F-surface plating layers 41n the first conductor pads (23A) are respectively filled in the first openings (27A) and each protrude in a bump-like shape to an outer side of the F-surface solder resist layer (29F). Further, similar to the F-surface plating layers 41 on the first conductor pads (23A), the F-surface plating layers 41 on the second conductor pads (23B) are also respectively filled in the second openings (27B) and each protrude in a bump-like shape to the outer side of the F-surface solder resist layer (29F). An amount of the protrusion from the outer surface of the second solder resist layer (29F) is substantially the same among the F-surface plating layers 41. The F-surface plating layers 41 are each formed by electroless Ni/Pd/Au metal layers. Of the electroless Ni/Pd/Au metal layers, the Ni layer (41L) has a thickness of 15-30 μm; the Pd layer (41M) has a thickness of 0.1-1 μm; and the Au layer (41N) has a thickness of 0.03-0.1 μm. A protruding height of the Ni layer (41L) from the upper surface of the solder resist layer 29 is 3-10 μm.

As illustrated in FIG. 1, in a B-surface solder resist layer (29B) on the B surface (100B) side of the wiring board 100 with a built-in electronic component, third openings 28 are formed that respectively expose portions of a B-surface outer side build-up conductor layer (22B) on the B surface (100B) side as third conductor pads 24. The third conductor pads 24 are connected via third via conductors 26 to the first build-up conductor layer (16A) (the build-up conductor layer 16 that is positioned on an outermost side) on the B surface (10B) side of the substrate 10 with a cavity.

The third via conductors 26 are formed by filling plating in third via formation holes 46 that penetrate through the outer side build-up insulating layer 21 and the protective layer 34. A hole diameter of the third via formation holes 46 is 50-100 μm, and an interval (pitch) between the third via formation holes (46, 46) is 0.2-1.5 mm. The third via formation holes 46 are each formed in a tapered shape similar to the first via formation holes (45A).

B-surface plating layers 42 are respectively formed on the third conductor pads 24. The B-surface plating layers 42 are respectively formed at bottoms of the third openings 28, and are recessed with respect to an outer surface of the B-surface solder resist layer (29B). Similar to the F-surface plating layers 41, the B-surface plating layers 42 are each formed by electroless Ni/Pd/Au metal layers. In each of the B-surface plating layers 42, the Ni layer has a thickness of 3-10 μm; the Pd layer has a thickness of 0.1-1 μm; and the Au layer has a thickness of 0.03-0.1 μm. A surface treatment of the B surface is not particularly limited, for example, may be a surface treatment in which electroless Ni/Au layers, an OSP layer and the like are formed.

The description about the structure of the wiring board 100 with a built-in electronic component is as given above. Next, a method for manufacturing the wiring board 100 with a built-in electronic component is described. Here, the wiring board 100 with a built-in electronic component is manufactured using the substrate 10 with a cavity. Therefore, in the following, first, a method for manufacturing the substrate 10 with a cavity is described.

The substrate 10 with a cavity is manufactured as follows.

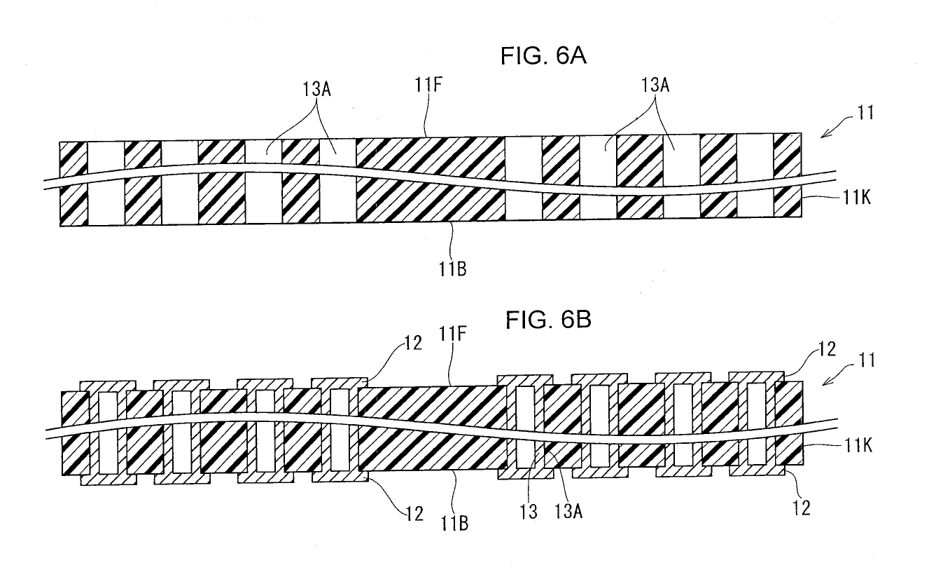

(1) As illustrated in FIG. 6A, the through holes (13A) are formed in the core substrate 11 by, for example, drilling or the like. The core substrate 11 is obtained by laminating a copper foil (not illustrated in the drawings) on each of both an F surface (11F), which is a front side surface of an insulating base material (11K), and a B surface (11B), which is a back side surface of the insulating base material (11K), the insulating base material (11K) being made of an epoxy resin or a BT (bismaleimide triazine) resin and a reinforcing material such as a glass cloth.

(2) By an electroless plating treatment, a plating resist treatment and an electrolytic plating treatment, the core conductor layer 12 is formed on each of the F surface (11F) and the B surface (11B) of the core substrate 11, and the through-hole conductors 13 are formed on the inner surfaces of the through holes (13A) (see FIG. 6B). A method for manufacturing the core substrate 11 may be a manufacturing method as illustrated in FIGS. 1 and 2 of Japanese Patent Laid-Open Publication No. 2012-69926. The entire contents of this publication are incorporated herein by reference.

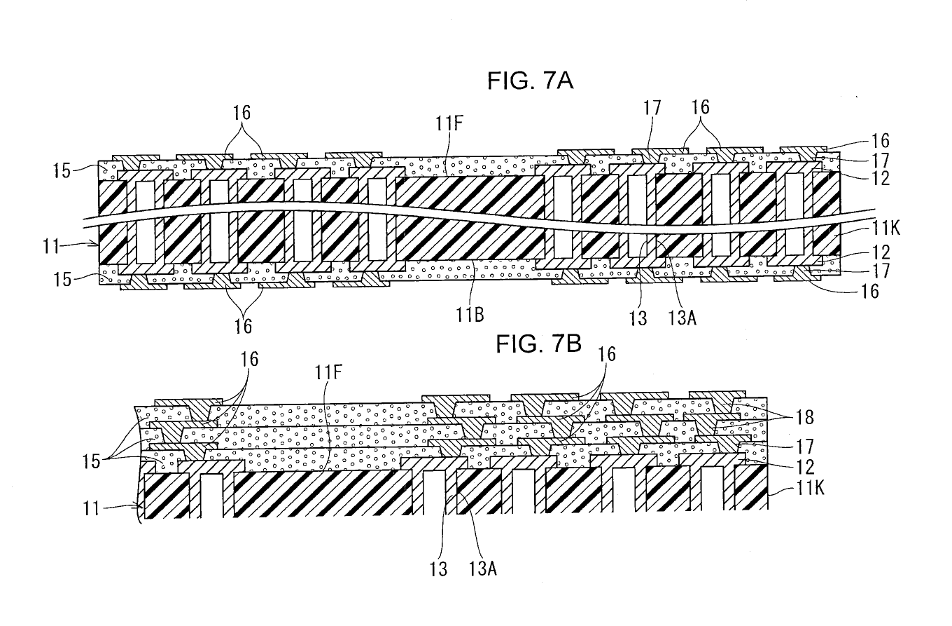

(3) As illustrated in FIG. 7A, a build-up insulating layer 15 is laminated on the core conductor layer 12, and a build-up conductor layer 16 is laminated on the build-up insulating layer 15. Specifically, a prepreg (a resin sheet of a B-stage formed by impregnating a core material with resin) as a build-up insulating layer 15 and a copper foil (not illustrated in the drawings) are laminated on the core conductor layer 12 on each of the F surface (11F) side and the B surface (11B) side of the core substrate 11. Then, the resulting substrate is hot-pressed. Then, CO2 laser is irradiated to the copper foil, and via formation holes that penetrate through the copper foil and the build-up insulating layer 15 are formed. Then, an electroless plating treatment, a plating resist treatment and an electrolytic plating treatment are performed. The via formation holes are filled with electrolytic plating and the via conductors 17 are formed, and a build-up conductor layer 16 of a predetermined pattern is formed on the build-up insulating layer 15. Instead of the prepreg, it is also possible to use a resin film that does not contain a core material as the build-up insulating layer 15. In this case, without laminating a copper foil, a conductor layer can be directly formed on a surface of the resin film using a semi-additive method.

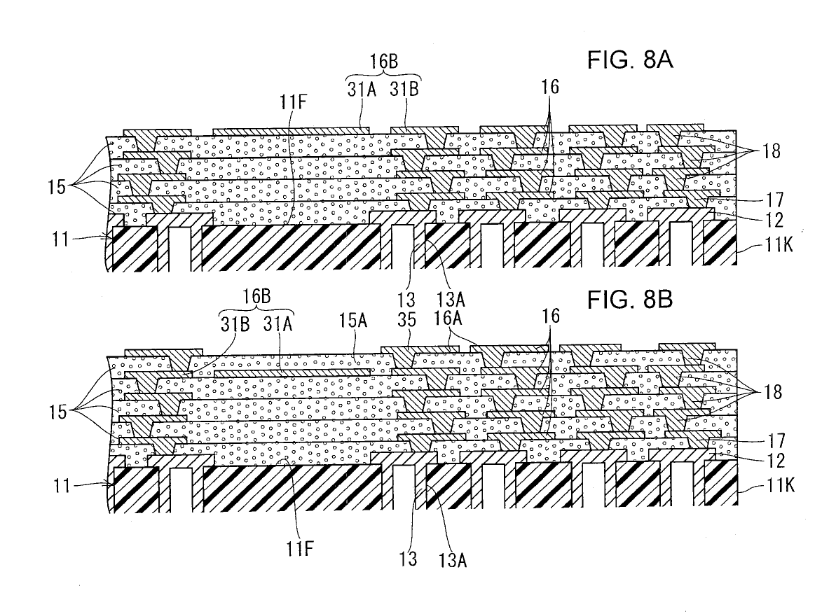

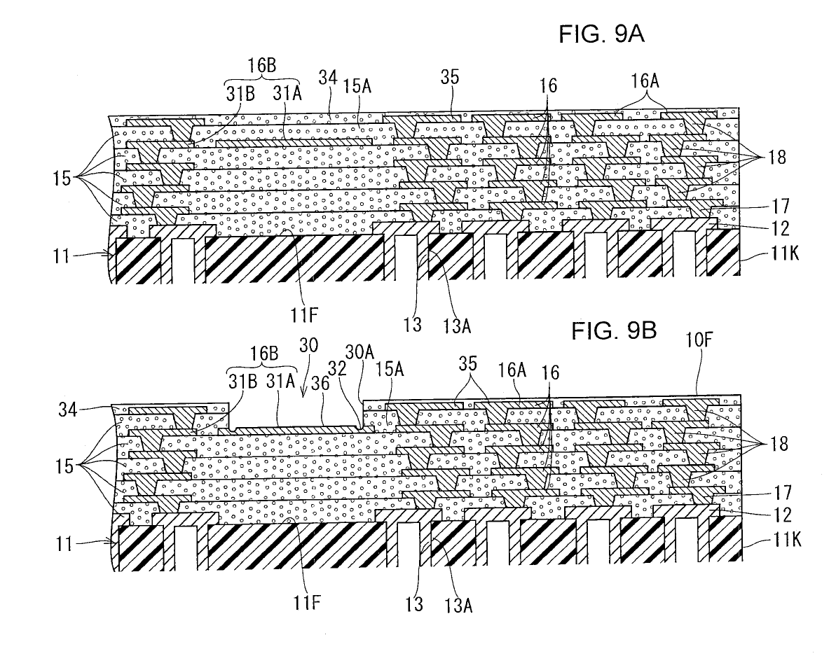

(4) Similar to the process of FIG. 7A, build-up insulating layers 15 and build-up conductor layers 16 are alternately laminated on each of the F surface (11F) side and the B surface (11B) side of the core substrate 11 (see FIG. 7B; in FIG. 7B, only the F surface (11F) side is illustrated; this applies also in FIG. 8A-9B in the following). In this case, the via conductors 18 that penetrate through a build-up insulating layer 15 are formed, and build-up insulating layers (16, 16) that are adjacent to each other in the lamination direction are connected by the via conductors 18.

(5) As illustrated in FIG. 8A, a build-up insulating layer 15 is laminated and a build-up conductor layer 16 is laminated on the build-up insulating layer 15, and the second build-up conductor layer (16B) is formed. In this case, the conductor circuit layer (31B), which is connected to an inner side build-up conductor layer 16 via the via conductors 18, and the solid-shaped plane layer (31A) are formed in the second build-up conductor layer (16B).

(6) As illustrated in FIG. 8B, on the second build-up conductor layer (16B), a build-up insulating layer 15 and a build-up conductor layer 16 are laminated, and the first build-up insulating layer (15A) and the first build-up conductor layer (16A) are formed. In this case, on the plane layer (31A), only the first build-up insulating layer (15A) is laminated. Further, in the first build-up conductor layer (16A), the outer side conductor circuit layer 35 is formed that is connected to the conductor circuit layer (31B) via the via conductors 18 that penetrate through the first build-up insulating layer (15A).

(7) As illustrated in FIG. 9A, on the first build-up conductor layer (16A), the protective layer 34 made of the same material as the build-up insulating layers 15 is laminated. In this case, on the plane layer (31A), the first build-up insulating layer (15A) and the protective layer 34 are laminated. However, the material of the protective layer 34 is not particularly limited, and may be, for example, an acrylic resin having an elastic modulus of 1-10 GPa, an epoxy resin, and an adhesive such as polyimide.

(8) As illustrated in FIG. 9B, by irradiating, for example, CO2 laser from the F surface (11F) side of the core substrate 11, the cavity 30 that exposes the plane layer (31A) as a bottom surface is formed in the protective layer 34 and the first build-up insulating layer (15A). Here, an area of a range in which laser is irradiated, that is, an opening area of the cavity 30, is smaller than an area of the plane layer (31A), so that the entire bottom surface of the cavity 30 is formed by the plane layer (31A) alone. Further, by strongly irradiating laser to an outer peripheral portion of the cavity 30, the recess 32 is formed in the outer peripheral portion of the portion of the plane layer (31A) that is exposed as the bottom surface of the cavity 30.

(9) The plane layer (31A) that is exposed as the bottom surface of the cavity 30 is subjected to a desmear treatment, and the roughened layer 36 is formed on the surface of the plane layer (31A) by a roughening treatment. When the desmear treatment is performed, the conductor circuit layer (31B) that is contained in the second build-up conductor layer (16B) is protected by the protective layer 34. As a result, the substrate 10 with a cavity illustrated in FIG. 4 is completed.

The above is the description of the method for manufacturing the substrate 10 with a cavity. Next, a method for manufacturing the wiring board 100 with a built-in electronic component using the substrate 10 with a cavity is described.

The wiring board 100 with a built-in electronic component is manufactured as follows.

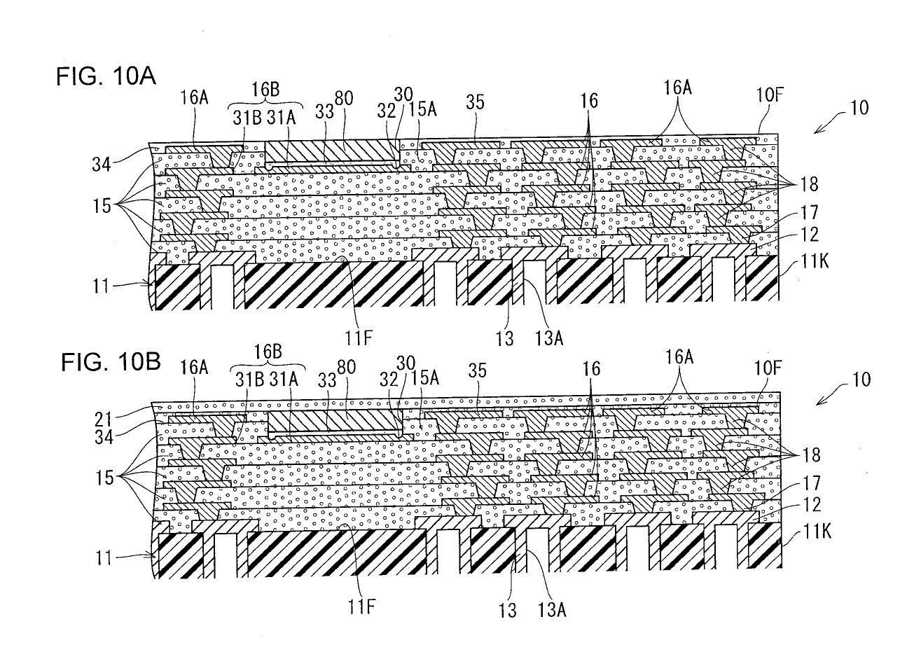

(1) As illustrated in FIG. 10A, the bonding layer 33 is laminated on the plane layer (31A) that is exposed as the bottom surface of the cavity 30, and the interposer 80 is placed on the bonding layer 33, and a thermal curing process and a CZ process are performed.

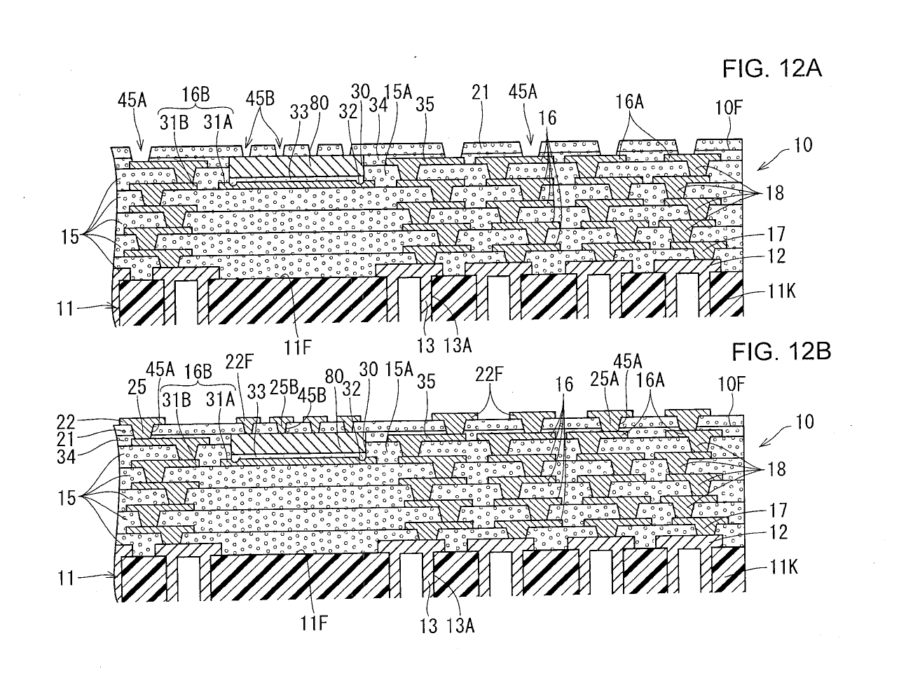

(2) The outer side build-up insulating layer 21 made of the same material as the build-up insulating layers 15 is laminated on each of the F surface (10F) and the B surface (10B) of the substrate 10 with a cavity (see FIG. 10B; in FIG. 10B, only the F surface (10F) side is illustrated; this applies also to FIGS. 12A and 12B).

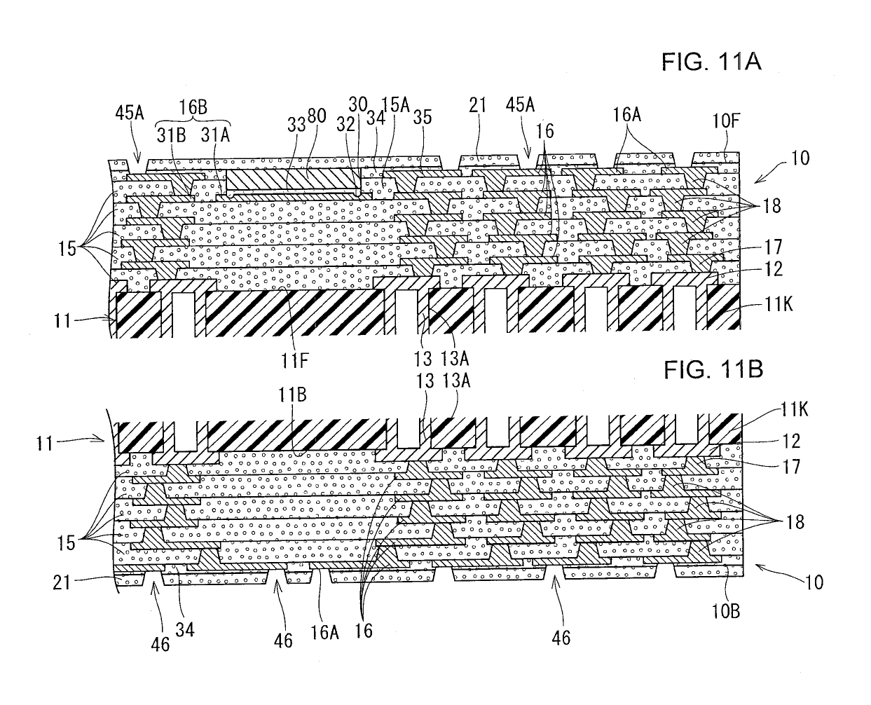

(3) The first via formation holes (45A) are formed in the outer side build-up insulating layer 21 and the protective layer 34 by irradiating infrared laser (for example, CO2 laser having a wavelength of 1-10 μm) from the F surface (10F) side of the substrate 10 with a cavity (see FIG. 11A), the third via formation holes 46 are formed by irradiating laser from the B surface (10B) side of the substrate 10 with a cavity (see FIG. 11B). Next, the second via formation holes (45B) that have a diameter smaller than that of the first via formation holes (45A) are formed in the outer side build-up insulating layer 21 by irradiating ultraviolet laser having a wavelength of 0.4 μm or less (for example, YAG laser) from the F surface (10F) side of the substrate 10 with a cavity (see FIG. 12A). The first build-up conductor layer (16A) and the interposer 80 that are exposed by the via formation holes (45A, 45B, 46) are subjected to a desmear treatment.

(4) An electroless plating treatment, a plating resist treatment and an electrolytic plating treatment are performed. The first via conductors (25A) and the second via conductors (25B) are respectively formed in the first via formation holes (45A) and the second via formation holes (45B) on the F surface (10F) side of the substrate 10 with a cavity (see FIG. 12B), and the third via conductors 26 are formed in the third via formation holes 46 on the B surface (10B) side of the substrate 10 with a cavity. Further, the outer side build-up conductor layers 22 (the F-surface outer side build-up conductor layer (22F) and the B-surface outer side build-up layer (22B)) are respectively formed on the outer side build-up insulating layers 21.

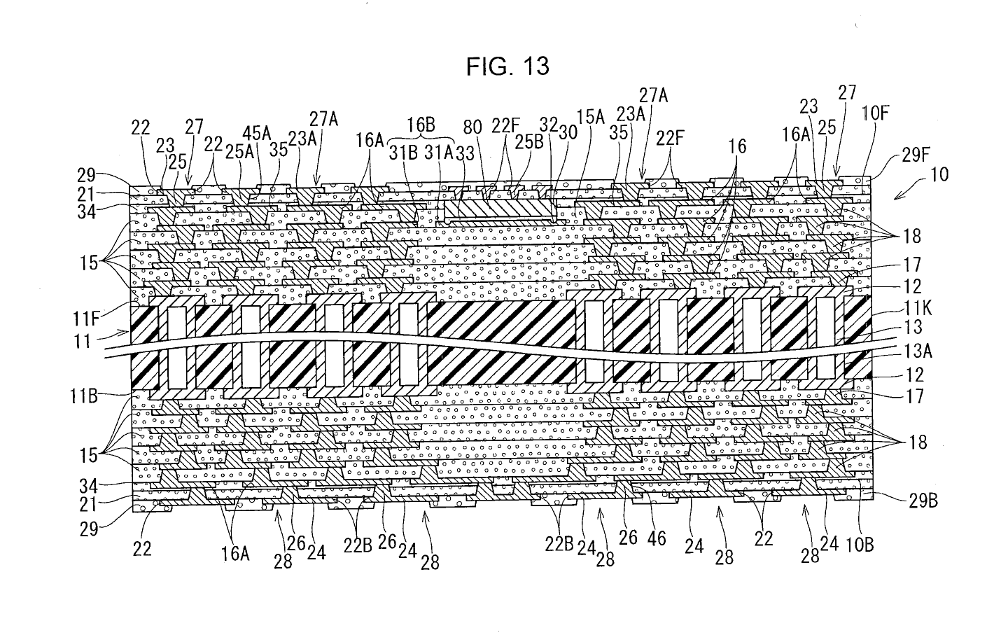

(5) As illustrated in FIG. 13, the solder resist layers 29 are respectively laminated on the outer side build-up conductor layers 22 from both the F surface (10F) side and the B surface (10B) side of the substrate 10 with a cavity; and, by a lithographic treatment, the first openings (27A) that respectively expose portions of the F-surface outer side build-up conductor layer (22F) as the first conductor pads (23A) are formed in the F-surface solder resist layer (29F) on the F surface (10F) side of the substrate 10 with a cavity, and the third openings 28 that respectively expose portions of the B-surface outer side build-up conductor layer (22B) as the third conductor pads 24 are formed in the B-surface solder resist layer (29B) on the B surface (10B) side.

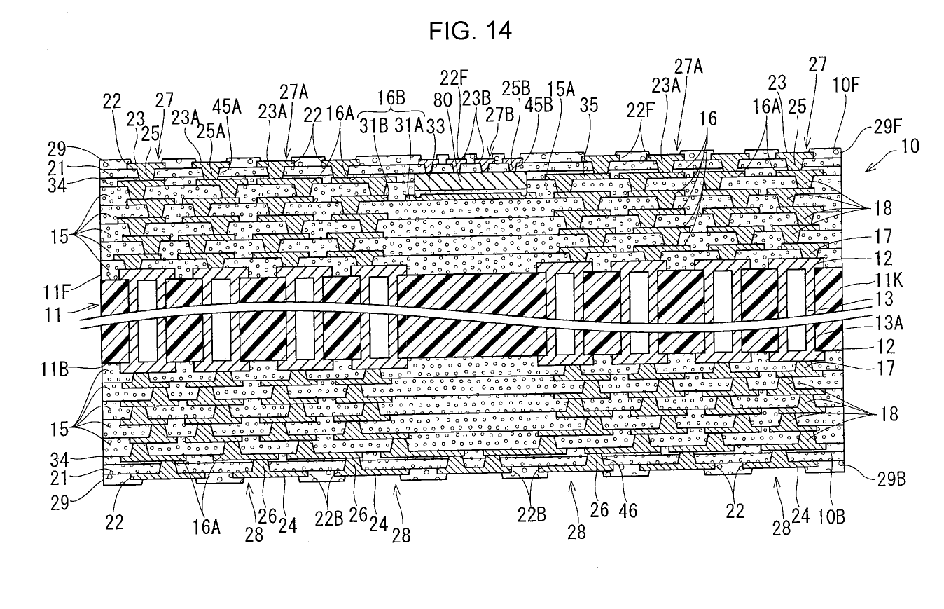

(6) As illustrated in FIG. 14, by irradiating ultraviolet laser from the F surface (10F) side of the substrate 10 with a cavity, the second openings (27B) that respectively expose portions of the F-surface outer side build-up conductor layer (22F) as the second conductor pads (23B) are formed. The second conductor pads (23B) are subjected to a desmear treatment.

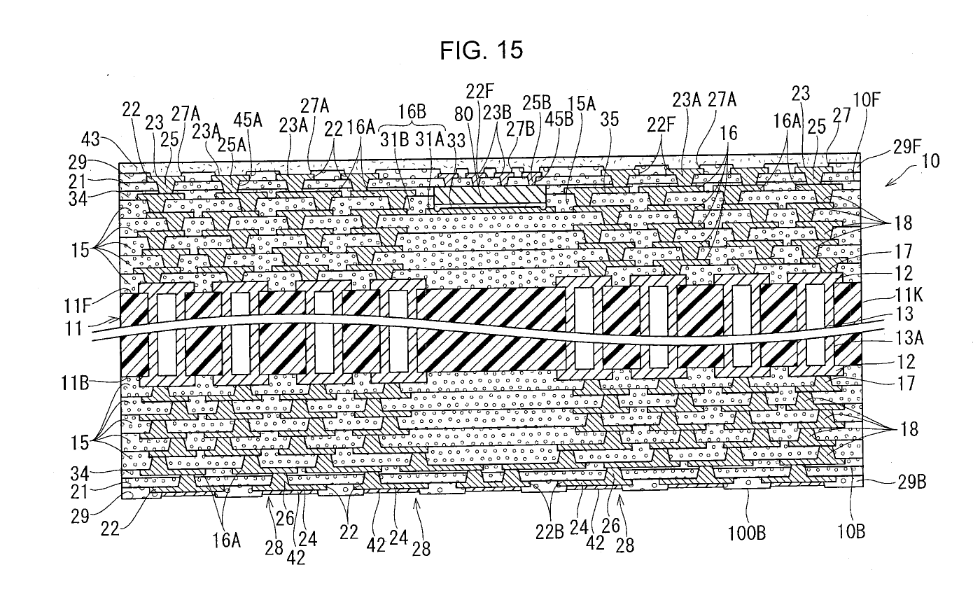

(7) As illustrated in FIG. 15, the F-surface solder resist layer (29F) is covered by a resin protective film 43. Then, the B surface (10B) side of the substrate 10 with a cavity is subjected to an electroless plating treatment, and the B-surface plating layers 42 are respectively formed on the third conductor pads 24. Specifically, first, the substrate in which the F-surface solder resist layer (29F) is covered by the resin protective film 43 is immersed in an electroless nickel plating solution for a predetermined period of time, and a Ni layer is formed. Next, the substrate is immersed in an electroless palladium plating solution for a predetermined period of time, and a Pd layer is formed. Further, the substrate is immersed in an electroless gold plating solution for a predetermined period of time, and an Au layer is formed. When the electroless plating treatment is performed, the second conductor pads (23B) and first conductor pads (23A) are protected by the resin protective film 43.

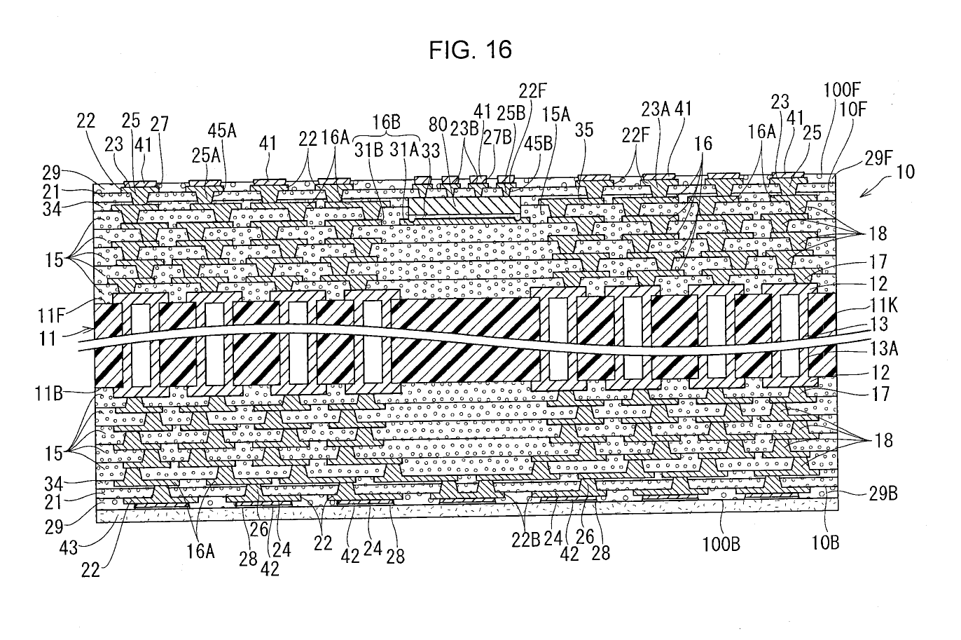

(8) As illustrated in FIG. 16, the resin protective film 43 that covers the resin F-surface solder resist layer (29F) is removed, and the B-surface solder resist layer (29B) is covered by a resin protective film 43. Then, similar to the process of FIG. 15, the F surface (10F) side of the substrate 10 with a cavity is subjected to an electroless plating treatment, and the F-surface plating layers 41 are respectively formed on the first conductor pads (23A) and the second conductor pads (23B). In doing so, the B-surface plating layer 42 is protected by the resin protective film 43.

(9) The resin protective film 43 that covers the B-surface solder resist layer (29B) is removed, and the wiring board 100 with a built-in electronic component illustrated in FIG. 1 is completed.

The description about the structure and the manufacturing method of the wiring board 100 with a built-in electronic component of the present embodiment is as given above. Next, an operation effect of the wiring board 100 with a built-in electronic component is described.

In the wiring board 100 with a built-in electronic component of the present embodiment, the first via formation holes (45A) that are formed on an outer side of the interposer 80 when viewed from the thickness direction and the second via formation holes (45B) that overlap with the interposer 80 are both formed by laser processing, and the wavelength of the laser used in the formation of the second via formation holes (45B) is shorter than the wavelength of the laser used in the formation of the first via formation holes (45A). Therefore, it is possible that the hole diameter of the second via formation holes (45B) is smaller than the hole diameter of the first via formation holes (45A). That is, in the wiring board 100 with a built-in electronic component of the present embodiment, the second via conductors (25B) that are respectively formed in the second via formation holes (45B) and are connected to the interposer 80 can be formed to have a small diameter along with miniaturization of the electrode terminals of the interposer 80, and the first via conductors (25A) that are respectively formed in the first via formation holes (45A) and are not connected to the interposer 80 can be formed to have a relatively large diameter. In this way, according to the wiring board 100 with a built-in electronic component of the present embodiment, while reduction in connection reliability of the first via conductors (25A) that are not connected to an electronic component can be suppressed, the second via conductors (25B) that are connected to an electronic component can be formed to have a small diameter to adapt to miniaturization of the electrode terminals of the electronic component.

Further, the wavelength of the laser that is used in the formation of the first via formation holes (45A) is longer than the wavelength of the laser that is used in the formation of the second via formation holes (45B). Therefore, time and effort required for the formation of the first via formation holes (45A) can be reduced as compared to a case where the first via formation holes (45A) are formed using the laser that is used in the formation of the second via formation holes (45B). In addition, in the present embodiment, the second via formation holes (45B) penetrate only the outer side build-up insulating layer 21, whereas the first via formation holes (45A) penetrate the protective layer 34 and the outer side build-up insulating layer 21. That is, the first via formation holes (45A) are longer than the second via formation holes (45B). Therefore, by allowing the wavelength of the laser used in the formation of the first via formation holes (45A) to be longer than the wavelength of the laser used in the formation of the second via formation holes (45B), the effect of reducing the time and effort required for the formation of the first via formation holes (45A) can be more enjoyed.

In addition, the second via formation holes (45B) are each formed in a tapered shape that has a taper angle smaller than that of the first via formation holes (45A). Therefore, a cross-sectional area of an end portion of each of the second via formation holes (45B) on a side connecting to the interposer 80 as an electronic component can be increased and reduction in connection reliability can be suppressed. Further, on the inner peripheral surface of the bottom portion of each of the second via formation holes (45B), the curved diameter-reducing portion 48 that is gradually reduced in diameter as it approaches the end on the bottom side is formed. Therefore, it becomes possible that, when the second via formation holes (45B) are filled with plating, voids are unlikely to occur at the bottom portions of the second via formation holes (45B). Further, by forming the curved diameter-reducing portion 48, stress concentration toward the via bottom of each of the second via conductors (25B) can be reduced, and crack prevention of the via bottom can be achieved.

### Other Embodiments

The present invention is not limited to the above-described embodiment. For example, embodiments described below are also included in the technical scope of the present invention. Further, in addition to the embodiments described below, the present invention can also be embodied in various modified forms within the scope without departing from the spirit of the present invention.

(1) In the above-described embodiment, as an electronic component, the interposer 80 is illustrated. However, the electronic component may also be a semiconductor element, and may also be a passive element such as a chip capacitor, an inductor, or a resistor.

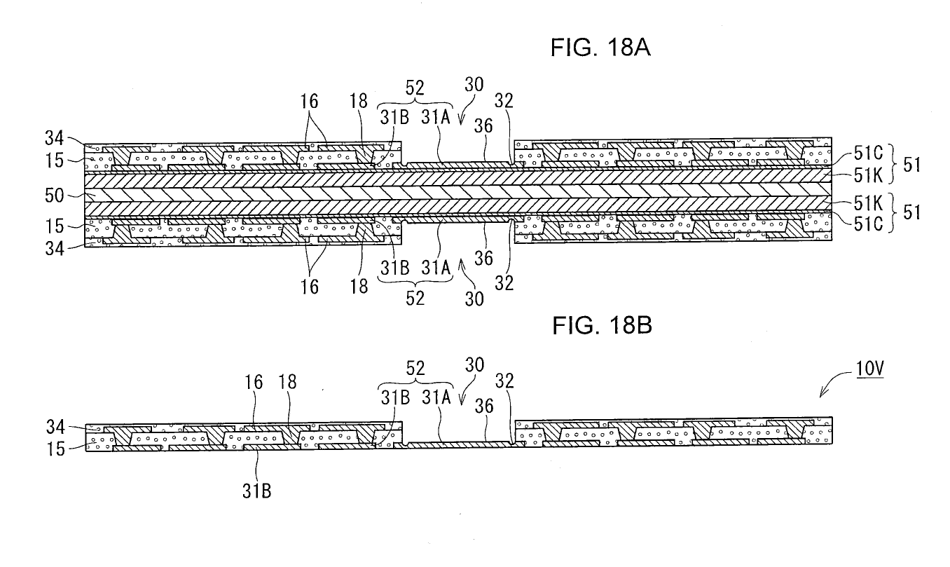

(2) In the above-described embodiment, the wiring board 100 with a built-in electronic component may also be a coreless substrate that does not have the core substrate 11. Specifically, the wiring board 100 with a built-in electronic component can have a coreless structure by using a substrate (10V) with a cavity illustrated in FIG. 18B. The substrate (10V) with a cavity can be manufactured using a method illustrated in the following processes 1-5.

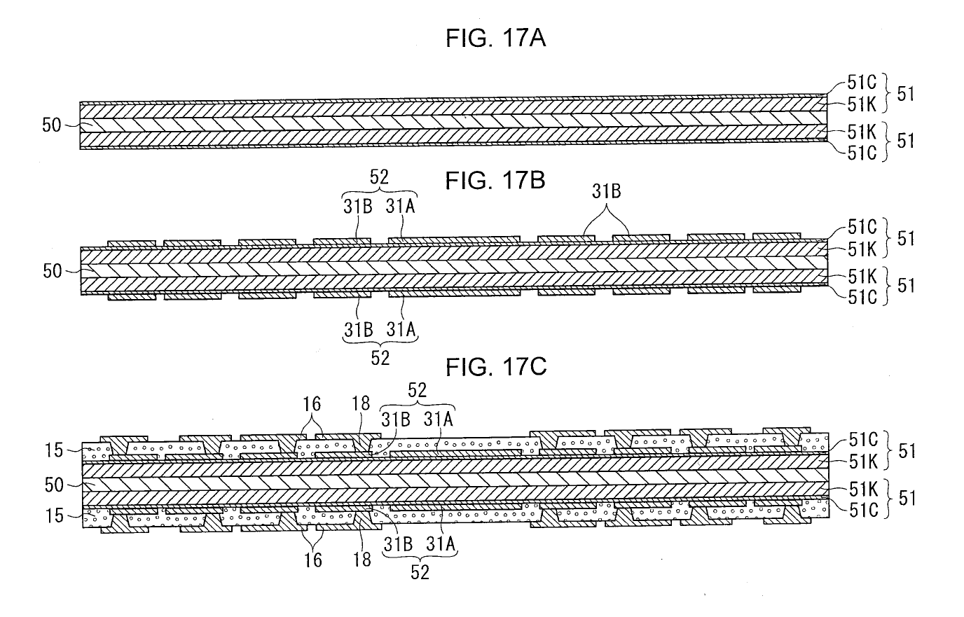

1. As illustrated in FIG. 17A, a copper foil 51 with a carrier that is formed by laminating a copper foil (51C) on an upper surface of a carrier (51K) is laminated on a support substrate 50. A bonding layer (not illustrated in the drawings) is formed between the carrier (51K) and the copper foil (51C) and between the carrier (51K) and the support substrate 50. An adhesive force between the carrier (51K) and the copper foil (51C) is weaker than an adhesive force between the carrier (51K) and the support substrate 50.

2. A plating resist of a predetermined pattern is formed on the copper foil (51C). Then, by an electrolytic plating treatment, an electrolytic plating film is formed in a non-forming part of the plating resist, and an inner side conductor layer 52 having a plane layer (31A) and a conductor circuit layer (31B) is formed on the copper foil (51C) (see FIG. 17B).

3. A build-up insulating layer 15 is laminated on the inner side conductor layer 52, and a build-up conductor layer 16 that is connected to the conductor circuit layer (31B) via vias 18 is formed on the build-up insulating layer 15 (see FIG. 17C).

4. A protective layer 34 is laminated on the build-up conductor layer 16. A cavity 30 that penetrates through the protective layer 34 and the build-up insulating layer 15 and exposes the plane layer (31A) as a bottom surface is formed by laser processing, and the bottom surface of the cavity 30 is subjected to a roughening treatment to form a roughened surface 36 (see FIG. 18A). In this case, a recess 32 is formed in an outer peripheral portion of the bottom surface of the cavity 30.

5. The carrier (51K) of the copper foil 51 with a carrier, and the support substrate 50, are peeled off Thereafter, the copper foil (51C) is removed by an etching process, and the substrate (10V) with a cavity is completed (see FIG. 18B). Thereafter, by the processes illustrated in FIG. 10-16 of the above-described embodiment, the wiring board 100 with a built-in electronic component can be formed to have a coreless structure.

(3) In the above-described embodiment, the laser used in the formation of the second via formation holes (45B) is ultraviolet light. However, it may also be visible light.

(4) In the above-described embodiment, each of the second via formation holes (45B) is formed in a tapered shape. However, it may also be formed in a straight shape.

In a wiring board with a built-in electronic component, when the electrode terminals of the electronic component are miniaturized, in accordance with the miniaturization, the via conductors that are connected to the electronic component are formed to each have a small diameter. However, in a wiring board with a built-in electronic component, there may be a problem that the laser used in the laser processing has a long wavelength and makes it difficult to make the diameter of each of the via conductors small. Further, even when the wavelength of the laser is short and the via conductors can be formed to each have a small diameter, there may be a problem that, when other via conductors that are not connected to the electronic component are formed to each have a small diameter, connection reliability of the other via conductors is reduced.

A wiring board with a built-in electronic component according to an embodiment of the present invention and a method for manufacturing a wiring board with a built-in electronic component are capable of adapting to miniaturization of electrode terminals of the electronic component while allowing reduction in connection reliability of via conductors to be suppressed.

According to one aspect of the present invention, a wiring board with a built-in electronic component includes: a substrate with a cavity that opens on one of a front side and a back side of the substrate; an electronic component that is accommodated in the cavity and has electrode terminals; an outer side insulating layer that is formed on the substrate with the cavity and on the electronic component; via formation holes that penetrate through the outer side insulating layer; and via conductors that are formed in the via formation holes. The via formation holes include first via formation holes that are formed on an outer side of the cavity when viewed from a thickness direction and second via formation holes that respectively expose the electrode terminals of the electronic component and have a diameter smaller than that of the first via formation holes. The first via formation holes and the second via formation holes are formed by laser processing, and the laser used in the formation of the second via formation holes has a wavelength shorter than that of the laser used in the formation of the first via formation holes.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board with a built-in electronic component, comprising:
a substrate having a cavity;
an electronic component accommodated in the cavity and having a plurality of electrode terminals;
an insulating layer formed on the substrate such that the insulating layer is covering the electronic component in the cavity; and
a plurality of via conductors formed through the insulating layer and comprising a plurality of first via conductors and a plurality of second via conductors such that the plurality of second via conductors is connected to the plurality of electrode terminals of the electronic component, respectively,
wherein the plurality of via conductors is formed in a plurality of via formation holes penetrating through the insulating layer, and the plurality of via formation holes comprises a plurality of first via formation holes and a plurality of second via formation holes such that the plurality of second via formation holes is exposing the plurality of electrode terminals of the electronic component, respectively, and that a second via formation hole has a diameter which is smaller than a diameter of a first via formation hole.

2. A wiring board with a built-in electronic component according to claim 1, wherein the first and second via formation holes are formed by laser processing such that the laser processing of the second via formation holes has a wavelength which is shorter than a wavelength of the laser processing of the first via formation holes.

3. A wiring board with a built-in electronic component according to claim 1, wherein the first and second via formation holes are formed such that each of the first via formation holes has a taper shape and the diameter reducing inward and each of the second via formation holes has one of a straight shape and a taper shape having a taper angle which is smaller than a taper angle of each of the first via formation holes.

4. A wiring board with a built-in electronic component according to claim 3, wherein each of the second via formation holes has a curved diameter-reducing portion formed at a bottom portion and curved such that the curved diameter-reducing portion has a diameter reducing toward the electronic component.

5. A wiring board with a built-in electronic component according to claim 1, wherein the first and second via formation holes are formed such that each of the first via formation holes has the diameter in a range of from 50 μm to 80 μm and each of the second via formation holes has the diameter in a range of from 20 μm to 40 μm.

6. A wiring board with a built-in electronic component according to claim 1, wherein the first and second via formation holes are formed such that adjacent first via formation holes have an interval in a range of from 70 μm to 160 μm and adjacent second via formation holes have an interval in a range of from 35 μm to 80 μm.

7. A wiring board with a built-in electronic component according to claim 1, wherein the plurality of first via formation holes is formed by infrared laser processing, and the plurality of second via formation holes is formed by UV laser processing.

8. A wiring board with a built-in electronic component according to claim 1, wherein the substrate comprises an inner insulating layer, a conductor circuit layer formed on the inner insulating layer, and a protective layer formed on the conductor circuit layer such that the insulating layer is formed on the protective layer, the plurality of first via formation holes is formed through the insulating layer and the protective layer of the substrate such that that the plurality of first via conductors is connected to the conductor circuit layer of the substrate, and the plurality of second via formation holes is formed through the insulating layer such that the plurality of second via conductors is connected to the plurality of electrode terminals of the electronic component, respectively.

9. A wiring board with a built-in electronic component according to claim 1, wherein the protective layer and inner insulating layer of the substrate comprise a same material.

10. A wiring board with a built-in electronic component according to claim 1, wherein the protective layer and inner insulating layer of the substrate are made of a same material.

11. A wiring board with a built-in electronic component according to claim 2, wherein the first and second via formation holes are formed such that each of the first via formation holes has a taper shape and the diameter reducing inward and each of the second via formation holes has one of a straight shape and a taper shape having a taper angle which is smaller than a taper angle of each of the first via formation holes.

12. A wiring board with a built-in electronic component according to claim 11, wherein each of the second via formation holes has a curved diameter-reducing portion formed at a bottom portion and curved such that the curved diameter-reducing portion has a diameter reducing toward the electronic component.

13. A wiring board with a built-in electronic component according to claim 2, wherein the first and second via formation holes are formed such that each of the first via formation holes has the diameter in a range of from 50 μm to 80 μm and each of the second via formation holes has the diameter in a range of from 20 μm to 40 μm.

14. A wiring board with a built-in electronic component according to claim 2, wherein the first and second via formation holes are formed such that adjacent first via formation holes have an interval in a range of from 70 μm to 160 μm and adjacent second via formation holes have an interval in a range of from 35 μm to 80 μm.

15. A wiring board with a built-in electronic component according to claim 2, wherein the plurality of first via formation holes is formed by infrared laser processing, and the plurality of second via formation holes is formed by UV laser processing.

16. A wiring board with a built-in electronic component according to claim 2, wherein the substrate comprises an inner insulating layer, a conductor circuit layer formed on the inner insulating layer, and a protective layer formed on the conductor circuit layer such that the insulating layer is formed on the protective layer, the plurality of first via formation holes is formed through the insulating layer and the protective layer of the substrate such that that the plurality of first via conductors is connected to the conductor circuit layer of the substrate, and the plurality of second via formation holes is formed through the insulating layer such that the plurality of second via conductors is connected to the plurality of electrode terminals of the electronic component, respectively.

17. A wiring board with a built-in electronic component according to claim 2, wherein the protective layer and inner insulating layer of the substrate comprise a same material.

18. A wiring board with a built-in electronic component according to claim 2, wherein the protective layer and inner insulating layer of the substrate are made of a same material.

19. A method for manufacturing a wiring board with a built-in electronic component, comprising:
accommodating an electronic component having a plurality of electrode terminals in a cavity of a substrate;
forming an insulating layer on the substrate such that the insulating layer is covering the electronic component in the cavity;
applying laser processing to the insulating layer such that a plurality of via formation holes is formed penetrating through the insulating layer; and
forming a plurality of via conductors in the plurality of via formation holes such that the plurality of via conductors is formed through the insulating layer,
wherein the applying of the laser processing comprises forming the plurality of via hole formation holes comprising a plurality of first via formation holes and a plurality of second via formation holes such that the plurality of second via formation holes is exposing the plurality of electrode terminals of the electronic component, respectively, and that a second via formation hole has a diameter which is smaller than a diameter of a first via formation hole, and the forming of the via conductors comprises forming the via conductors comprising a plurality of first via conductors and a plurality of second via conductors such that the plurality of second via conductors is connected to the plurality of electrode terminals of the electronic component, respectively.

20. A method for manufacturing a wiring board with a built-in electronic component according to claim 19, wherein the applying of the laser processing comprises applying infrared laser upon the insulating layer such that the plurality of first via formation holes is formed, and applying UV laser upon the insulating layer such that the plurality of second via formation holes is formed.
